(19) United States
(12) Patent Application Publication
(10) Pub. No.: US 2024/0204146 A1
(43) Pub. Date: Jun. 20, 2024

(54) DISPLAY DEVICE

(71) Applicant: LG Display Co., Ltd., Seoul (KR)

(72) Inventors: Sumin LEE, Seoul (KR); Hun JANG, Paju-si (KR)

(21) Appl. No.: 18/526,862

(22) Filed: Dec. 1, 2023

(30) Foreign Application Priority Data
Dec. 16, 2022 (KR) 10-2022-0177434

(51) Int. Cl. H01L 33/44; H01L 25/16; H01L 33/38

(52) U.S. Cl. CPC H01L 33/44; H01L 25/167; H01L 33/387; H01L 2933/0025

(57) ABSTRACT

Provided is a display device that includes a substrate having thereon a plurality of sub pixels, first and second assembly lines which are spaced apart from each other, a first upper planarization layer on the first assembly line and the second assembly line and has an opening overlapping the first assembly line and the second assembly line. The device includes a light emitting diode on the opening and includes a first electrode, a first semiconductor layer, an emission layer, a second semiconductor layer, and a second electrode, a contact electrode which couples the first assembly line and the second assembly line and the first electrode, and an organic insulating layer above the first upper planarization layer and in a part of the opening and covers a part of a side surface of the light emitting diode. Thus, a fixing force of a light emitting diode can be improved.

### CROSS-REFERENCE TO RELATED APPLICATIONS

This application claims the priority of Korean Patent Application No. 10-2022-0177434 filed on Dec. 16, 2022, in the Korean Intellectual Property Office, the disclosure of which is incorporated herein by reference.

### BACKGROUND

### Technical Field

The present disclosure relates to a display device, and more particularly, to a display device using a light emitting diode (LED).

### Description of the Related Art

As display devices which are used for a monitor of a computer, a television, or a cellular phone, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance may be displayed.

### BRIEF SUMMARY

Various embodiments of the present disclosure provide a display device which improves a fixing force of a light emitting diode.

Various embodiments of the present disclosure provide a display device with an improved efficiency of a manufacturing process.

The technical benefits of the present disclosure are not limited to the above-mentioned benefits, and other benefits, which are not mentioned above, can be clearly understood by those skilled in the art from the following descriptions.

According to an aspect of the present disclosure, there is provided a display device. The display device comprises a substrate including a plurality of sub pixels, a first assembly line and a second assembly line which are disposed in the plurality of sub pixels on the substrate and are spaced apart from each other, a first upper planarization layer which is disposed on the first assembly line and the second assembly line and has an opening overlapping the first assembly line and the second assembly line, a light emitting diode which is disposed on the opening and includes a first electrode, a first semiconductor layer, an emission layer, a second semiconductor layer, and a second electrode, a contact electrode which electrically connects the first assembly line and the second assembly line and the first electrode, and an organic insulating layer which is disposed above the first upper planarization layer and in a part of the opening and covers a part of a side surface of the light emitting diode. Thus, a fixing force of a light emitting diode can be improved.

Other detailed matters of the exemplary embodiments are included in the detailed description and the drawings.

According to the present disclosure, the movement of the light emitting diode after self-assembly is reduced or minimized and the fixing force of the light emitting diode may be improved.

According to the present disclosure, an efficiency of a bonding process of the light emitting diode may be improved.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2 is an enlarged plan view of a display device according to an exemplary embodiment of the present disclosure;

FIG. 3 is an enlarged plan view of a region X of FIG. 2;

FIG. 4A is a cross-sectional view taken along the lines A-A′ of FIG. 2 and B-B′ of FIG. 3;

FIG. 4B is a cross-sectional view taken along the line C-C′ of FIG. 3;

FIG. 4C is a cross-sectional view taken along the line D-D′ of FIG. 3;

FIGS. 5A to 5F are process diagrams for explaining a forming process of a display device according to an exemplary embodiment of the present disclosure;

FIG. 6 is an enlarged plan view of a display device according to another exemplary embodiment of the present disclosure;

FIG. 7 is an enlarged plan view of a display device according to still another exemplary embodiment of the present disclosure;

FIG. 8 is an enlarged plan view of a display device according to still another exemplary embodiment of the present disclosure;

FIG. 9A is an enlarged plan view of a display device according to still another exemplary embodiment of the present disclosure; and

FIG. 9B is a cross-sectional view taken along the line E-E′ of FIG. 9A.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, number of elements, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

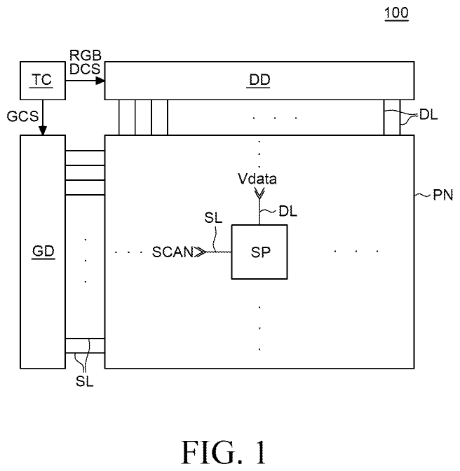

FIG. 1 is a schematic diagram of a display device according to an exemplary embodiment of the present disclosure.

In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The display panel PN is a configuration which displays images to the user and includes the plurality of sub pixels SP. In the display panel PN, the plurality of scan lines SL and the plurality of data lines DL overlap each other and the plurality of sub pixels SP is connected to the scan lines SL and the data lines DL, respectively. In addition, each of the plurality of sub pixels SP may be connected to a high potential power line VDD, a low potential power line, a reference line RL, and the like.

The plurality of sub pixels SP is a minimum unit which configures a screen and each of the plurality of sub pixels SP may include a light emitting diode and a pixel circuit for driving the light emitting diode. The plurality of light emitting diodes may be defined in different manners depending on the type of the display panel PN. For example, when the display panel PN is an inorganic light emitting display panel, the light emitting diode may be a light emitting diode (LED) or a micro light emitting diode (micro LED).

The gate driver GD supplies a plurality of scan signals SCAN to a plurality of scan lines SL in accordance with a plurality of gate control signals GCS supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data RGB input from the timing controller TC in accordance with a plurality of data control signals DCS supplied from the timing controller TC into a data voltage Vdata using a reference gamma voltage. The data driver DD may supply the converted data voltage Vdata to the plurality of data lines DL.

The timing controller TC aligns image data RGB input from the outside to supply the image data to the data driver DD. The timing controller TC may generate a gate control signal GCS and a data control signal DCS using synchronization signals input from the outside, such as a dot clock signal, a data enable signal, and horizontal/vertical synchronization signals. Further, the timing controller TC supplies the generated gate control signal GCS and data control signal DCS to the gate driver GD and the data driver DD, respectively, to control the gate driver GD and the data driver DD.

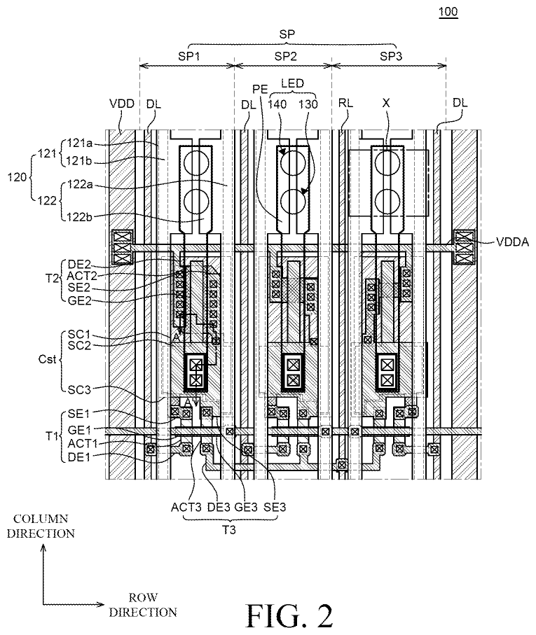

Hereinafter, the display panel PN of the display device 100 will be described in more detail with reference to FIGS. 2 to 4 together.

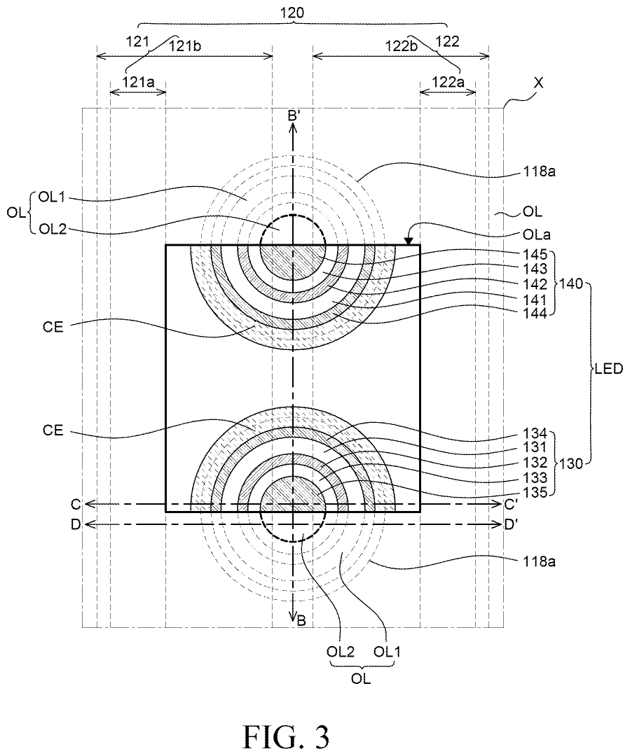

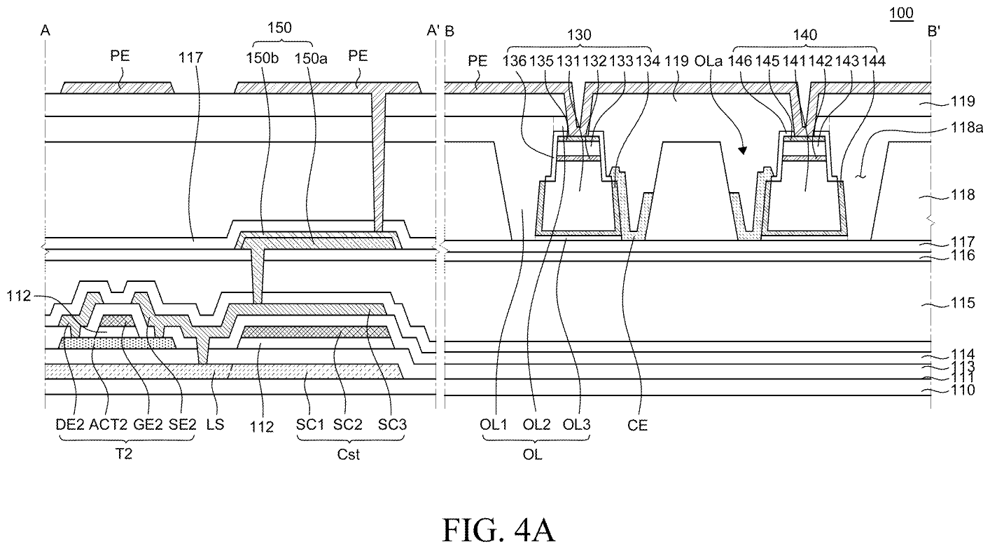

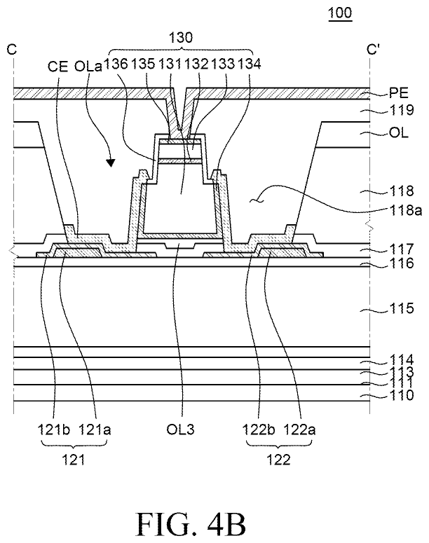

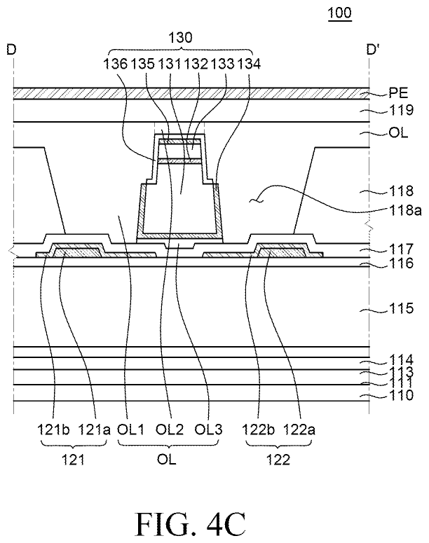

FIG. 2 is an enlarged plan view of a display device according to an exemplary embodiment of the present disclosure. FIG. 3 is an enlarged plan view of a region X of FIG. 2. FIG. 4A is a cross-sectional view taken along the lines A-A′ of FIG. 2 and B-B′ of FIG. 3. FIG. 4B is a cross-sectional view taken along the line C-C′ of FIG. 3. FIG. 4C is a cross-sectional view taken along the line D-D′ of FIG. 3. Referring to FIG. 2, each of the plurality of sub pixels SP includes a first transistor T1, a second transistor T2, a third transistor T3, a storage capacitor Cst, and one or more light emitting diodes LED. In FIG. 2, for the simplicity of the drawing, the hatching of the assembly line 120 and the light emitting diode LED is omitted, the contact electrode CE is not illustrated, and the organic insulating layer OL is not illustrated. In FIG. 3, the pixel electrode PE is not illustrated.

Referring to FIG. 2, the display device 100 includes a first sub pixel SP1 disposed in a first column, a second sub pixel SP2 disposed in a second column, and a third sub pixel SP3 disposed in a third column which are repeatedly disposed in the row direction.

Each of the first sub pixel SP1, the second sub pixel SP2, and the third sub pixel SP3 includes a light emitting diode LED and a pixel circuit to independently emit light. For example, the first sub pixel SP1 is a red sub pixel, the second sub pixel SP2 is a green sub pixel, and the third sub pixel SP3 may be a blue sub pixel, but it is not limited thereto. Further, the pixel circuit may include a first transistor T1, a second transistor T2, and a third transistor T3 and a storage capacitor Cst.

The display panel PN includes a substrate 110, a buffer layer 111, a gate insulating layer 112, an interlayer insulating layer 113, a first passivation layer 114, a lower planarization layer 115, a second passivation layer 116, a third passivation layer 117, a first upper planarization layer 118, an organic insulating layer OL, and a second upper planarization layer 119.

The substrate 110 is a component for supporting various components included in the display panel PN and may be formed of an insulating material. For example, the substrate 110 may be formed of glass, resin, or the like. Further, the substrate 110 may be configured to include polymer or plastics or may be formed of a material having flexibility.

A high potential power line VDD, a plurality of data lines DL, a reference line RL, an assembly line 120, a light shielding layer LS, and a first capacitor electrode SC1 are disposed on the substrate 110.

The high potential power line VDD is a wiring line which transmits a high potential power voltage to each of the plurality of sub pixels SP. The plurality of high potential power lines VDD may transmit the high potential power voltage to the second transistor T2 of each of the plurality of sub pixels SP. The high potential power line VDD may extend along a column direction between the plurality of sub pixels SP. For example, the high potential power line VDD may be disposed to extend along a column direction between the first sub pixel SP1 and the third sub pixel SP3. Further, the high potential power line VDD may transmit a high potential power voltage to each of the plurality of sub pixels SP disposed in the row direction through an auxiliary high potential power line VDDA to be described below. In this case, the high potential voltage line VDD may be referred to as a first power line. Further, the column direction may be referred to as a first direction and the row direction may be referred to as a second direction.

The plurality of data lines DL is wiring lines which transmit the data voltage Vdata to each of the plurality of sub pixels SP. The plurality of data lines DL may be connected to the first transistor T1 of each of the plurality of sub pixels SP. The plurality of data lines DL may extend along a column direction between the plurality of sub pixels SP. For example, a data line DL which extends between the first sub pixel SP1 and the high potential power line VDD in the column direction transmits a data voltage Vdata to the first sub pixel SP1. A data line DL disposed between the first sub pixel SP1 and the second sub pixel SP2 transmits a data voltage Vdata to the second sub pixel SP2. Further, a data line DL disposed between the third sub pixel SP3 and the high potential power line VDD may transmit a data voltage Vdata to the third sub pixel SP3.

The reference lines RL is a wiring line which transmits a reference voltage to the plurality of sub pixels SP. The reference line RL may be connected to the third transistor T3 of each of the plurality of sub pixels SP. The reference line RL may extend along a column direction between the plurality of sub pixels SP. For example, the reference line RL may be disposed to extend along a column direction between the second sub pixel SP2 and the third sub pixel SP3. Further, a third drain electrode DE3 of the third transistor T3 of each of the first sub pixel SP1, the second sub pixel SP2, and the third sub pixel SP3 adjacent to the reference line RL extends in the row direction to be electrically connected to the reference line RL. In this case, the reference voltage line RL may be referred to as a third power line.

The light shielding layer LS is disposed on the substrate 110 in each of the plurality of sub pixels SP. The light shielding layer LS blocks light which is incident to the transistor from the lower portion of the substrate 110 to reduce or minimize a leakage current. For example, the light shielding layer LS may block light incident to a second active layer ACT2 of the second transistor T2 which is a driving transistor.

In each of the plurality of sub pixels SP, a first capacitor electrode SC1 is disposed on the substrate 110. The first capacitor electrode SC1 may form a storage capacitor Cst together with the other capacitor electrode. The first capacitor electrode SC1 may be integrally formed with the light shielding layer LS.

A buffer layer 111 is disposed on the high potential power line VDD, the plurality of data lines DL, the reference line RL, the light shielding layer LS, and the first capacitor electrode SC1. The buffer layer 111 may reduce permeation of moisture or impurities through the substrate 110. The buffer layer 111 may be configured by a single layer or a double layer of silicon oxide (SiOₓ) or silicon nitride (SiNₓ), but is not limited thereto. However, the buffer layer 111 may be omitted depending on a type of substrate 110 or a type of transistor, but is not limited thereto.

First, the first transistor T1 is disposed on the buffer layer 111 in each of the plurality of sub pixels SP. The first transistor T1 is a transistor which transmits a data voltage Vdata to the second gate electrode GE2 of the second transistor T2. The first transistor T1 is turned on by a scan signal from the scan line SL and a data voltage Vdata from the data line DL is transmitted to the second gate electrode GE2 of the second transistor T2 through the turned-on first transistor T1. Accordingly, the first transistor T1 may be referred to as a switching transistor.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be formed of a semiconductor material such as an oxide semiconductor, amorphous silicon, or polysilicon, but is not limited thereto.

The gate insulating layer 112 is disposed on the first active layer ACT1. The gate insulating layer 112 is an insulating layer which insulates the first active layer ACT1 from the first gate electrode GE1 and may be configured by a single layer or a double layer of silicon oxide (SiOₓ) or silicon nitride (SiNₓ), but is not limited thereto.

The first gate electrode GE1 is disposed on the gate insulating layer 112. The first gate electrode GE1 may be electrically connected to the scan line SL. The first gate electrode GE1 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the first gate electrode GE1. A contact hole is formed in the interlayer insulating layer 113 to allow the first source electrode SE1 and the first drain electrode DE1 to be connected to the first active layer ACT1. The interlayer insulating layer 113 is an insulating layer which protects components below the interlayer insulating layer 113 and may be configured by a single layer or a double layer of silicon oxide (SiOₓ) or silicon nitride (SiNₓ), but is not limited thereto.

A first source electrode SE1 and a first drain electrode DE1 which are electrically connected to the first active layer ACT1 are disposed on the interlayer insulating layer 113. The first drain electrode DE1 may be connected to the data line DL and the first active layer ACT1, and the first source electrode SE1 is connected to the first active layer ACT1 and the second gate electrode GE2 of the second transistor T2. The first source electrode SE1 and the first drain electrode DE1 may be configured by a conductive material, such as copper (Cu), aluminum (Al), molybdenum (Mo), nickel (Ni), titanium (Ti), chrome (Cr), or an alloy thereof, but are not limited thereto.

The second transistor T2 is disposed on the buffer layer 111 in each of the plurality of sub pixels SP. The second transistor T2 is a transistor which supplies a driving current to the light emitting diode LED. The second transistor T2 is turned on to control the driving current flowing to the light emitting diode LED. Accordingly, the second transistor T2 which controls the driving current may be referred to as a driving transistor.

The second transistor T2 includes a second active layer ACT2, a second gate electrode GE2, a second source electrode SE2, and a second drain electrode DE2.

The second active layer ACT2 is disposed on the buffer layer 111. The second active layer ACT2 may be formed of a semiconductor material such as an oxide semiconductor, amorphous silicon, or polysilicon, but is not limited thereto.

The gate insulating layer 112 is disposed on the second active layer ACT2 and the second gate electrode GE2 is disposed on the gate insulating layer 112. The second gate electrode GE2 may be electrically connected to the first source electrode SE1 of the first transistor T1. The second gate electrode GE2 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the second gate electrode GE2, and the second source electrode SE2 and the second drain electrode DE2 which are electrically connected to the second active layer ACT2 are disposed on the interlayer insulating layer 113. The second drain electrode DE2 may be electrically connected to the second active layer ACT2 and the high potential power line VDD, and the second source electrode SE2 may be electrically connected to the second active layer ACT2 and the light emitting diode LED. The second source electrode SE2 and the second drain electrode DE2 may be configured by a conductive material, such as copper (Cu), aluminum (Al), molybdenum (Mo), nickel (Ni), titanium (Ti), chrome (Cr), or an alloy thereof, but are not limited thereto.

The third transistor T3 is disposed on the buffer layer 111 in each of the plurality of sub pixels SP. The third transistor T3 is a transistor for compensating for a threshold voltage of the second transistor T2. The third transistor T3 is connected between the second source electrode SE2 of the second transistor T2 and the reference line RL. The third transistor T3 is turned on to transmit the reference voltage to the second source electrode SE2 of the second transistor T2 to sense a threshold voltage of the second transistor T2. Accordingly, the third transistor T3 which senses a characteristic of the second transistor T2 may be referred to as a sensing transistor.

The third transistor T3 includes a third active layer ACT3, a third gate electrode GE3, a third source electrode SE3, and a third drain electrode DE3.

The third active layer ACT3 is disposed on the buffer layer 111. The third active layer ACT3 may be formed of a semiconductor material such as an oxide semiconductor, amorphous silicon, or polysilicon, but is not limited thereto.

The gate insulating layer 112 is disposed on the third active layer ACT3 and the third gate electrode GE3 is disposed on the gate insulating layer 112. The third gate electrode GE3 may be electrically connected to the scan line SL. The third gate electrode GE3 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the third gate electrode GE3, and the third source electrode SE3 and the third drain electrode DE3 which are electrically connected to the third active layer ACT3 are disposed on the interlayer insulating layer 113. The third drain electrode DE3 may be electrically connected to the third active layer ACT3 and the reference line RL and the third source electrode SE3 may be electrically connected to the third active layer ACT3 and the second source electrode SE2 of the second transistor T2. The third source electrode SE3 and the third drain electrode DE3 may be configured by a conductive material, such as copper (Cu), aluminum (Al), molybdenum (Mo), nickel (Ni), titanium (Ti), chrome (Cr), or an alloy thereof, but are not limited thereto.

Both the first transistor T1 and the third transistor T3 illustrated in FIG. 2 are transistors which are connected to the scan line SL to be controlled, but are not limited thereto, the pixel circuit may include transistors connected to an emission line EL.

The second capacitor electrode SC2 is disposed on the gate insulating layer 112. The second capacitor electrode SC2 is one of electrodes which form the storage capacitor Cst and may be disposed to overlap the first capacitor electrode SC1. The second capacitor electrode SC2 is integrally formed with the second gate electrode GE2 of the second transistor T2 to be electrically connected to the second gate electrode GE2. The first capacitor electrode SC1 and the second capacitor electrode SC2 may be disposed to be spaced apart from each other with the buffer layer 111 and the gate insulating layer 112 therebetween.

Further, the plurality of scan lines SL, the auxiliary high potential power line VDDA, and a third capacitor electrode SC3 are disposed on the interlayer insulating layer 113.

First, the scan line SL is a wiring line which transmits the scan signal SCAN to each of the plurality of sub pixels SP. The scan line SL may extend in the row direction while traversing the plurality of sub pixels SP. The scan line SL may be electrically connected to the first gate electrode GE1 of the first transistor T1 and the third gate electrode GE3 of the third transistor T3 of each of the plurality of sub pixels SP.

The auxiliary high potential power line VDDA is disposed on the interlayer insulating layer 113. The auxiliary high potential power line VDDA extends in the row direction to be disposed to traverse the plurality of sub pixels SP. The auxiliary high potential power line VDDA may be electrically connected to the high potential power line VDD extending in the column direction and the second drain electrode DE2 of the second transistor T2 of each of the plurality of sub pixels SP disposed along the row direction.

The third capacitor electrode SC3 is disposed on the interlayer insulating layer 113. The third capacitor electrode SC3 is an electrode which forms the storage capacitor Cst and may be disposed to overlap the first capacitor electrode SC1 and the second capacitor electrode SC2. The third capacitor electrode SC3 is integrally formed with the second source electrode SE2 of the second transistor T2 to be electrically connected to the second source electrode SE2. Further, the second source electrode SE2 is electrically connected to the first capacitor electrode SC1 through a contact hole formed in the interlayer insulating layer 113 and the buffer layer 111. Therefore, the first capacitor electrode SC1 and the third capacitor electrode SC3 may be electrically connected to the second source electrode SE2 of the second transistor T2.

The storage capacitor Cst stores a potential difference between the second gate electrode GE2 and the second source electrode SE2 of the second transistor T2 while the light emitting diode LED emits light, so that a constant current is supplied to the light emitting diode LED. The storage capacitor Cst includes the first capacitor electrode SC1, the second capacitor electrode SC2, and the third capacitor electrode SC3 to store a voltage between the second gate electrode GE2 and the second source electrode SE2 of the second transistor T2. The first capacitor electrode SC1 is formed on the substrate 110 and is connected to the second source electrode SE2 and the second capacitor electrode SC2 is formed on the buffer layer 111 and the gate insulating layer 112 and is connected to the second gate electrode GE2. The third capacitor electrode SC3 is formed on the interlayer insulating layer 113 and is connected to the second source electrode SE2.

The first passivation layer 114 is disposed on the first transistor T1, the second transistor T2, the third transistor T3, and the storage capacitor Cst. The first passivation layer 114 is an insulating layer which protects components below the first passivation layer 114 and may be configured by a single layer or a double layer of silicon oxide (SiOₓ) or silicon nitride (SiNₓ), but is not limited thereto.

The lower planarization layer 115 is disposed on the first passivation layer 114. The lower planarization layer 115 may planarize an upper portion of the substrate 110 on which the plurality of transistors T1, T2, and T3 and the storage capacitor Cst are disposed. The lower planarization layer 115 may be configured by a single layer or a double layer, and for example, may be formed of photoresist or an acrylic-based organic material, but is not limited thereto.

The second passivation layer 116 is disposed on the lower planarization layer 115. The second passivation layer 116 is an insulating layer which protects components below the second passivation layer 116 and may be configured by a single layer or a double layer of silicon oxide (SiOₓ) or silicon nitride (SiNₓ), but is not limited thereto.

The connection electrode 150 and the plurality of assembly lines 120 are disposed on the second passivation layer 116.

The connection electrode 150 is an electrode which electrically connects the second transistor T2 and the pixel electrode PE. The connection electrode 150 may be electrically connected to the second source electrode SE2 which also serves as the third capacitor electrode SC3 through a contact hole formed in the second passivation layer 116, the lower planarization layer 115, and the first passivation layer 114.

The connection electrode 150 may have a double-layered structure formed by a first connection layer 150a and a second connection layer 150b. The first connection layer 150a is disposed on the second passivation layer 116 and the second connection layer 150b which covers the first connection layer 150a is disposed. The second connection layer 150b may be disposed to enclose all a top surface and side surfaces of the first connection layer 150a.

The second connection layer 150b is formed of a material which is more resistant to corrosion than the first connection layer 150a so that when the display device 100 is manufactured, the short defect due to the migration between the first connection layer 150a and the adjacent wiring line may be reduced or minimized. For example, the first connection layer 150a is formed of a conductive material, such as copper (Cu) or chrome (Cr) and the second connection layer 150b is formed of molybdenum (Mo) or titanium molybdenum (MoTi), but are not limited thereto.

A plurality of assembly lines 120 is disposed on the second passivation layer 116.

The plurality of assembly lines 120 includes a plurality of first assembly lines 121 and a plurality of second assembly lines 122.

The plurality of first assembly lines 121 and the plurality of second assembly lines 122 extend in the column direction in each of the first sub pixel SP1, the second sub pixel SP2, and the third sub pixel SP3 and may be disposed to be spaced apart from each other with a selected interval (or in some embodiments, predetermined interval).

The plurality of assembly lines 120 is disposed in an area overlapping the low potential power line to be electrically connected to the low potential power line. The low potential power line is wiring lines which transmit a low potential power voltage to the light emitting diode LED. The low potential power line may extend in the column direction in each of the plurality of sub pixels SP. For example, the low potential power line may be disposed in each of the first sub pixel SP1, the second sub pixel SP2, and the third sub pixel SP3.

Each of the plurality of assembly lines 120 includes conductive layers 121a and 122a disposed on the second passivation layer 116 and clad layers 121b and 122b which are disposed on the conductive layers 121a and 122a and cover all the top surface and side surfaces of the conductive layers 121a and 122a.

The first assembly line 121 includes the first conductive layer 121a and the first clad layer 121b and the second assembly line 122 includes the second conductive layer 122a and the second clad layer 122b.

The first conductive layer 121a and the second conductive layer 122a do not overlap the light emitting diode LED. That is, ends of the first conductive layer 121a and the second conductive layer 122a may be disposed at the outside from the end of the light emitting diode LED.

The first clad layer 121b of the first assembly line 121 may be disposed so as to cover the top surface and the side surfaces of the first conductive layer 121a and the second clad layer 122b of the second assembly line 122 may be disposed so as to cover the top surface and the side surfaces of the second conductive layer 122a. At this time, the first clad layer 121b and the second clad layer 122b extend to a central portion of the light emitting diode LED from ends of the first conductive layer 121a and the second conductive layer 122a respectively to overlap the light emitting diode LED. For example, the first clad layer 121b and the second clad layer 122b may be disposed so as to overlap an area corresponding to less than a half of the area of the bottom surface of the light emitting diode LED.

The first conductive layer 121a and the second conductive layer 122a may be formed of the same material by the same process as the first connection layer 150a of the connection electrode 150. For example, the first conductive layer 121a and the second conductive layer 122a may be formed of a conductive material, such as copper (Cu) and chrome (Cr). The first clad layer 121b and the second clad layer 122b may be formed of the same material by the same process as the second connection layer 150b of the connection electrode 150. For example, the first clad layer 121b and the second clad layer 122b are formed of a material which is more resistant to corrosion than the first conductive layer 121a and the second conductive layer 122a, for example, molybdenum (Mo) or titanium molybdenum (MoTi), but is not limited thereto.

The third passivation layer 117 is disposed on the connection electrode 150 and the assembly line 120. The third passivation layer 117 is an insulating layer which protects components below the third passivation layer 117 and may be configured by a single layer or a double layer of silicon oxide (SiOₓ) or silicon nitride (SiNₓ), but is not limited thereto.

A partial area of the third passivation layer 117 may be open in an area adjacent to the plurality of light emitting diodes LED. For example, the third passivation layer 117 may expose a part of top surfaces of the first assembly line 121 and the second assembly line 122 in an area adjacent to one side surface of the plurality of light emitting diodes LED.

The first upper planarization layer 118 is disposed on the third passivation layer 117. The first upper planarization layer 118 may planarize an upper portion of the third passivation layer 117. The first upper planarization layer 118 may cover a part of the first clad layer 121b of the first assembly line 121 and a part of the second clad layer 122b of the second assembly line 122.

The first upper planarization layer 118 may be configured by a single layer or a double layer, and for example, may be formed of an acrylic-based organic material, but is not limited thereto.

In the meantime, the first upper planarization layer 118 includes a plurality of openings 118a disposed in positions corresponding to the plurality of sub pixels SP. The plurality of openings 118a is a portion in which the plurality of light emitting diodes LED is inserted and may be also referred to as pockets.

One opening 118a may be disposed so as to overlap parts of the first assembly line 121 and the second assembly line 122 which are disposed to be adjacent to each other in one sub pixel SP. That is, a part of the first clad layer 121b of the first assembly line 121 and a part of the second clad layer 122b of the second assembly line 122 may be disposed at the inside of an opening 118a in which the first upper planarization layer 118 is not disposed.

A partial area of the third passivation layer 117 may be open in the plurality of openings 118a. For example, as illustrated in FIGS. 4A to 4C, the third passivation layer 117 may exposes a part of top surfaces of the first assembly line 121 and the second assembly line 122 in an area excluding the area in which the organic insulating layer OL is disposed, from the plurality of openings 118a.

In the plurality of openings 118a, the plurality of light emitting diodes LED is disposed on the third passivation layer 117. One or more light emitting diodes LED are disposed in one sub pixel SP. As illustrated in FIG. 2, two light emitting diodes LED may be disposed in one sub pixel SP. The light emitting diode LED is an element which emits light by the current. The light emitting diode LED includes a light emitting diode LED which emits red light, green light, and blue light and may implement various color light including white by a combination thereof. Further, various color light may be implemented using the light emitting diode LED which emits specific color light and a light conversion member which converts light from the light emitting diode LED into another color light.

The light emitting diode LED is supplied with a driving current from the second transistor T2 to emit light. The light emitting diode LED may include a red light emitting diode, a green light emitting diode, and a blue light emitting diode. For example, a light emitting diode LED disposed in the first sub pixel SP1 is a red light emitting diode, a light emitting diode LED disposed in the second sub pixel SP2 is a green light emitting diode, and a light emitting diode LED disposed in the third sub pixel SP3 may be a blue light emitting diode, but is not limited thereto.

At this time, the plurality of light emitting diodes LED disposed in one sub pixel SP may be connected in parallel. That is, one electrode of each of the plurality of light emitting diodes LED is connected to the source electrode SE2 of the same second transistor T2 and the other electrode may be connected to the same assembly line 120.

The light emitting diode LED may include a first light emitting diode 130 and a second light emitting diode 140. The light emitting diode LED disposed in each of the plurality of sub pixels SP may be disposed in the column direction. For example, as illustrated in FIGS. 2 and 3, the second light emitting diode 140 may be disposed above the first light emitting diode 130.

The first light emitting diode 130 may emit the same color light as the second light emitting diode 140. In this case, the first light emitting diode 130 and the second light emitting diode 140 are the same type of light emitting diodes LED so that the size of the first light emitting diode 130 may be equal to the size of the second light emitting diode 140. Here, the size of the light emitting diode LED may refer to an area of a bottom surface of the light emitting diode, a width on the cross section, a volume, or a height, but is not limited thereto.

Even though in FIGS. 2 and 4, for the convenience of description, it is illustrated that two light emitting diodes LED are disposed in each of the plurality of sub pixels SP, the number of light emitting diodes LED which is disposed in each of the plurality of sub pixels SP is not limited thereto.

Referring to FIGS. 3 to 4C, the light emitting diode 130 includes a first semiconductor layer 131, an emission layer 132, a second semiconductor layer 133, a first electrode 134, a second electrode 135, and an encapsulation layer 136.

The first semiconductor layer 131 is disposed on the third passivation layer 117 and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers formed by doping p-type and n-type impurities into a material, such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium (Ge), tin (Sn), and the like, but are not limited thereto.

A part of the first semiconductor layer 131 may be disposed to outwardly protrude from the second semiconductor layer 133. A top surface of the first semiconductor layer 131 may be formed by a part overlapping a bottom surface of the second semiconductor layer 133 and a part disposed at an outside of the bottom surface of the second semiconductor layer 133. However, sizes and shapes of the first semiconductor layer 131 and the second semiconductor layer 133 are modified in various forms, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN) or gallium nitride (GaN), but is not limited thereto.

The first electrode 134 which encloses a bottom surface and side surfaces of the first semiconductor layer 131 is disposed. The first electrode 134 is an electrode which electrically connects the first light emitting diode 130 and the assembly line 120. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the top surface of the second semiconductor layer 133. The second electrode 135 is an electrode which electrically connects a pixel electrode PE to be described below and the second semiconductor layer 133. The second electrode 135 is formed of a conductive material, for example, a transparent conductive material, such as indium tin oxide (ITO) or indium zinc oxide (IZO), but is not limited thereto.

The encapsulation layer 136 which encloses at least a part of the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. The encapsulation layer 136 may be disposed so as to cover the emission layer 132, a part of a side surface of the first semiconductor layer 131 adjacent to the emission layer 132, and a part of a side surface of the second semiconductor layer 133 adjacent to the emission layer 132. The first electrode 134 and the second electrode 135 may be exposed from the encapsulation layer 136 and a contact electrode CE and a pixel electrode PE to be formed later and the first electrode 134 and the second electrode 135 may be electrically connected.

Referring to FIG. 4A, the second light emitting diode 140 is disposed on the third passivation layer 117. The second light emitting diode 140 is disposed above the first light emitting diode 130 and is disposed in one sub pixel SP together with the first light emitting diode 130 and the pixel circuit.

The second light emitting diode 140 includes a first semiconductor layer 141, an emission layer 142, a second semiconductor layer 143, a first electrode 144, a second electrode 145, and an encapsulation layer 146. The first semiconductor layer 141, the emission layer 142, the second semiconductor layer 143, the second electrode 145, and the encapsulation layer 146 of the second light emitting diode 140 are substantially the same as the first semiconductor layer 131, the emission layer 132, the second semiconductor layer 133, the second electrode 135, and the encapsulation layer 136 of the first light emitting diode 130. Accordingly, a redundant description will be omitted.

The second light emitting diode 140 is electrically connected to the first light emitting diode 130 and the pixel electrode PE extending from the pixel circuit through the contact hole formed in the organic insulating layer OL and the second upper planarization layer 119. Therefore, in one sub pixel SP, the first light emitting diode 130 and the second light emitting diode 140 may be electrically connected to the second transistor T2.

The contact electrode CE is disposed at the inside of the opening 118a. The contact electrode CE is an electrode which electrically connects the first assembly line 121 and the second assembly line 122 disposed at the inside of the opening 118a to the first electrodes 134 and 144 of the light emitting diode LED.

The contact electrode CE may be in contact with the side surface of the light emitting diode LED in an area excluding an area in which a first part OL1 of the organic insulating layer OL is disposed. For example, the contact electrode CE is disposed at the inside of the opening 118a to be in contact with at least a part of the first electrodes 134 and 144. At this time, the contact electrode CE is in contact with the first clad layer 121b of the first assembly line 121 and the second clad layer 122b of the second assembly line 122 in an area in which the third passivation layer 117 is open and may electrically connect the first assembly line 121 and the second assembly line 122 and the first electrodes 134 and 144.

In the meantime, the contact electrode CE may be configured by a conductive material such as copper (Cu), aluminum (Al), molybdenum (Mo), nickel (Ni), titanium (Ti), chrome (Cr), or an alloy thereof.

The organic insulating layer OL is disposed on the first upper planarization layer 118. The organic insulating layer OL is also disposed at the inside of the opening 118a to be in partially contact with the plurality of light emitting diodes LED. For example, the organic insulating layer OL may cover a part of a side surface and a part of a top surface of the plurality of light emitting diodes LED. At this time, the plurality of light emitting diodes LED may be stably fixed to the inside of the opening 118a by means of the organic insulating layer OL.

The organic insulating layer OL may be formed of an acrylic-based organic material, but is not limited thereto.

The organic insulating layer OL includes a first part OL1, a second part OL2, and a third part OL3.

The first part OL1 is a part which is in contact with a side surface of the light emitting diode LED, among a top surface, a bottom surface, and a side surface of the plurality of light emitting diodes LED. Accordingly, the first part OL1 may be a part of the organic insulating layer OL disposed in the opening 118a. In the meantime, the first part OL1 may be disposed in a part excluding the part of the side surface of the light emitting diode LED which is in contact with the contact electrode CE.

The first part OL1 may overlap both the first assembly line 121 and the second assembly line 122 in the opening 118a. At this time, the first part OL1 is disposed on the third passivation layer 117 in the opening 118a to be disposed to overlap the first assembly line 121 and the second assembly line 122. At this time, referring to FIG. 3, a size of an area of the first part OL1 which overlaps the first assembly line 121 may be equal to a size of an area of the first part OL1 which overlaps the second assembly line 122.

The first part OL1 of the organic insulating layer OL extends to the outside of the opening 118a to be disposed on the first upper planarization layer 118.

The second part OL2 of the organic insulating layer OL is a part which is disposed on the top surface of the light emitting diode LED, among the top surface, the bottom surface, and the side surfaces of the plurality of light emitting diodes LED to cover a part of the top surface of the light emitting diode LED. Therefore, the side surface of the second part OL2 may be disposed along parts of circumferences of the second electrodes 135 and 145.

The second part OL2 is disposed on top surfaces of the plurality of light emitting diodes LED to fix the light emitting diode LED without being separated. The third part OL3 is a part which is disposed below the bottom surface of the light emitting diode LED, among the top surface, the bottom surface, and the side surface of the plurality of light emitting diodes LED.

The third part OL3 of the organic insulating layer OL may be disposed in a space between the third passivation layer 117 and the light emitting diode LED. Therefore, the third part OL3 may be in contact with the bottom surface of the light emitting diode LED. Further, the third part OL3 may be disposed so as to overlap the third passivation layer 117 disposed on the first assembly line 121 and the second assembly line 122, below the plurality of light emitting diodes LED. At this time, the third part OL3 may serve as an adhesive layer to fix the light emitting diode LED to the third passivation layer 117.

The second upper planarization layer 119 is disposed on the organic insulating layer OL and an organic insulating layer opening OLa in which the organic insulating layer is not formed. The second upper planarization layer 119 may planarize an upper portion of the substrate 110 on the organic insulating layer OL.

The second upper planarization layer 119 may be configured by a single layer or a double layer, and for example, may be formed of an acrylic-based organic material, but is not limited thereto.

The second upper planarization layer 119 is filled in the opening 118a and may planarize an upper portion of the substrate 110 in which the plurality of light emitting diodes LED is disposed. For example, the second upper planarization layer 119 may be filled in the opening 118a in an area excluding an area of the opening 118a in which the organic insulating layer OL is disposed. Therefore, the second upper planarization layer 119 may be disposed on the contact electrode CE at the inside of the opening 118a. A planar shape of the second upper planarization layer 119 disposed in the opening 118a may be a rectangular shape, as illustrated in FIG. 3.

In the meantime, the second upper planarization layer 119 may be in contact with a part of side surfaces of the plurality of light emitting diodes LED and a part of a top surface of the light emitting diode LED in the opening 118a. At this time, referring to FIGS. 4A to 4C, the second upper planarization layer 119 includes a contact hole which exposes a part of the top surface of the light emitting diode LED. The pixel electrode PE is disposed in the contact hole of the second upper planarization layer 119 to be electrically connected to the second electrodes 135 and 145 of the plurality of light emitting diodes LED.

The pixel electrode PE is disposed on the second upper planarization layer 119.

The pixel electrode PE is an electrode which electrically connects the plurality of light emitting diodes LED and the connection electrode 150. The pixel electrode PE is electrically connected to the pixel circuit and the pixel electrode PE is disposed to extend to the first light emitting diode 130 and the second light emitting diode 140. That is, the pixel electrode PE extends to the first light emitting diode 130 to be connected to the second light emitting diode 140 and may be electrically connected to the connection electrode 150 and the second transistor T2 through the contact hole formed in the second upper planarization layer 119.

In the meantime, referring to FIG. 4B, the pixel electrode PE may be disposed on the plurality of light emitting diodes LED in an area in which the organic insulating layer OL is not disposed. At this time, the pixel electrode PE may be in contact with the second electrodes 135 and 145 without forming a separate contact hole in the second part OL2 of the organic insulating layer OL, in an area excluding an area of the top surface of the plurality of light emitting diodes LED, in which the second part OL2 is disposed.

The pixel electrode PE may be formed of a conductive material, for example, a transparent conductive material, such as indium tin oxide (ITO) or indium zinc oxide (IZO), but is not limited thereto.

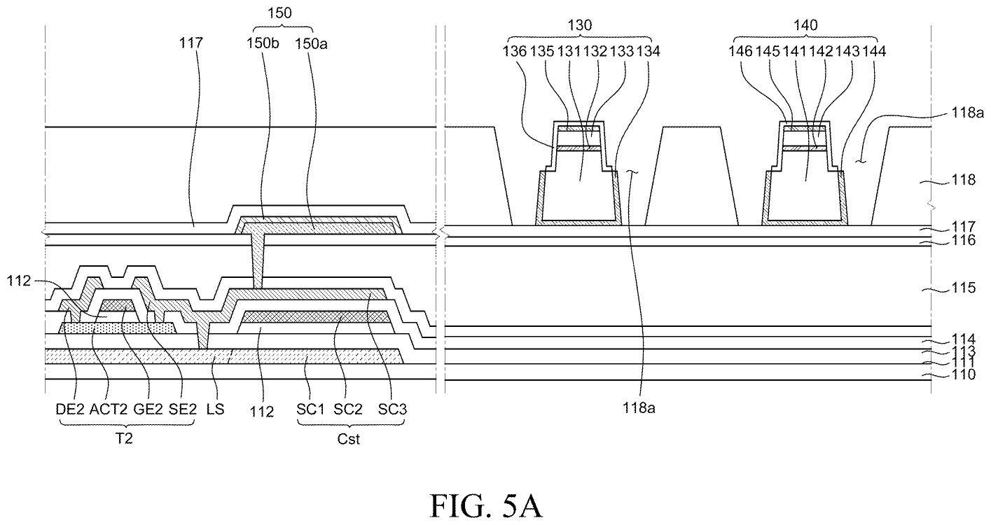

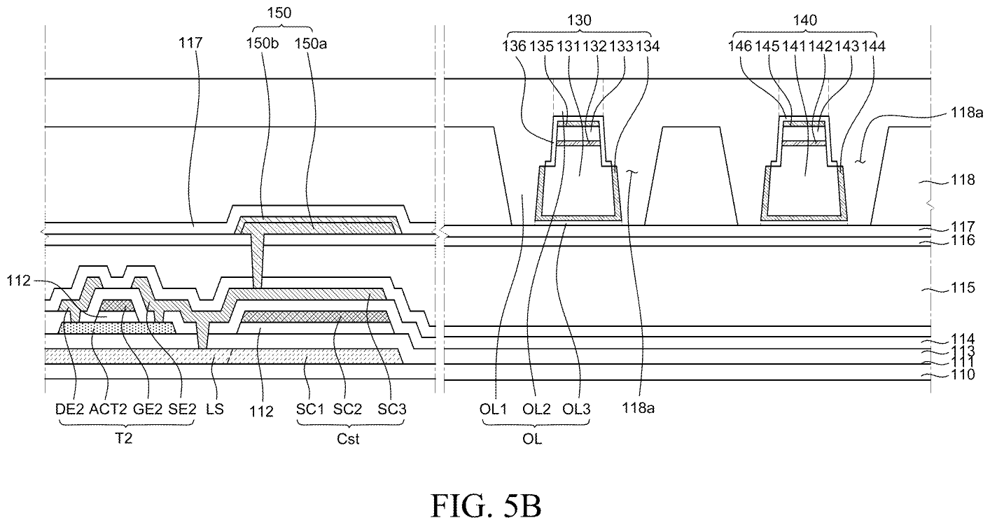

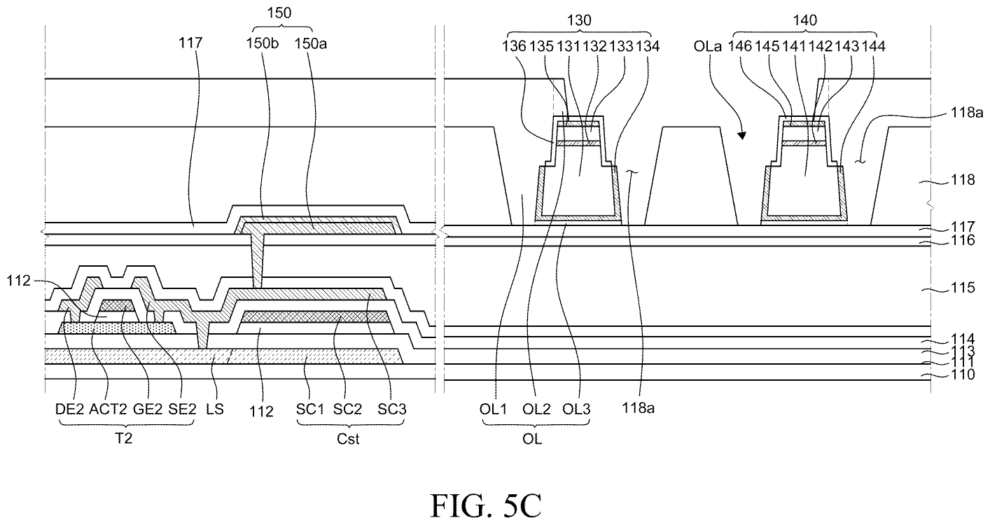

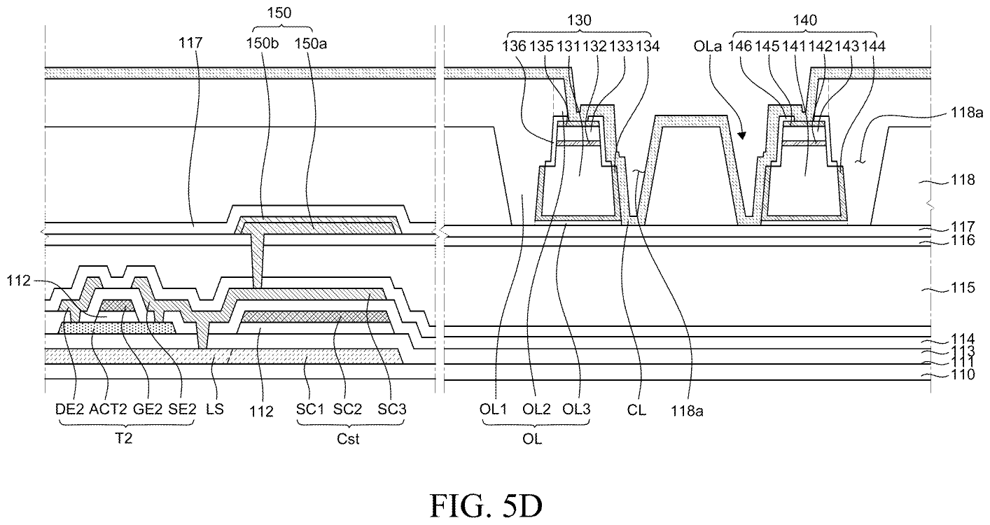

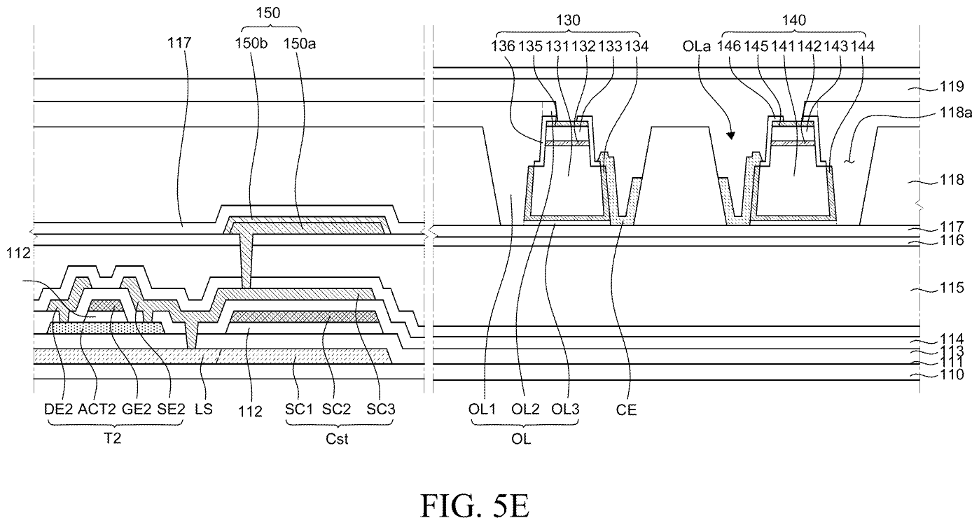

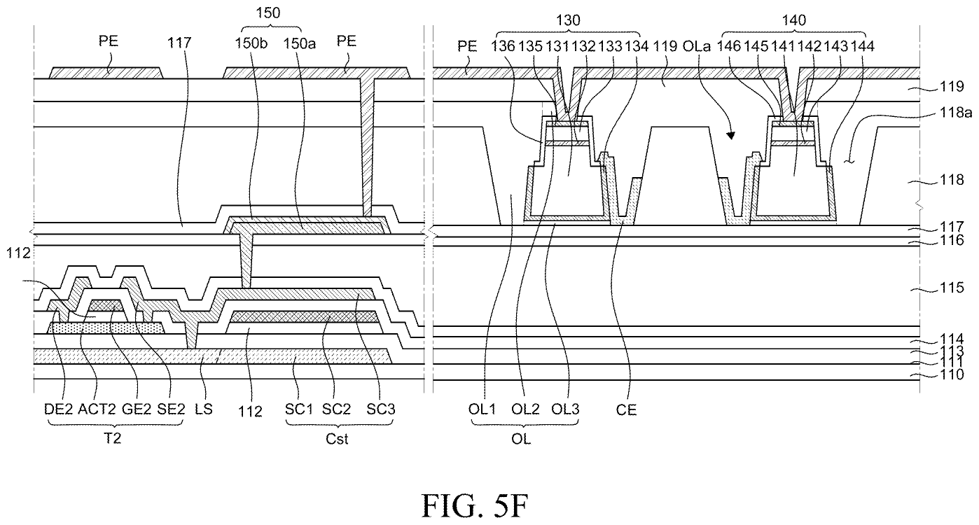

Hereinafter, a manufacturing method of a display device 100 will be described with reference to FIGS. 5A to 5F.

FIGS. 5A to 5F are process diagrams for explaining a forming process of a display device according to an exemplary embodiment of the present disclosure.

Referring to FIG. 5A, the light emitting diode LED may be self-assembled at the inside of the opening 118a using the first assembly line 121 and the second assembly line 122. The first upper planarization layer 118 provides a pocket which is a space in which the light emitting diode LED is seated and the light emitting diode LED may be seated on the third passivation layer 117 disposed at the inside of the opening 118a.

Next, referring to FIG. 5B, an organic insulating layer OL is formed on an entire surface of the substrate 110. Specifically, the organic insulating layer OL may be formed on the first upper planarization layer 118 and the light emitting diode LED. The organic insulating layer OL may be formed at the inside of the opening 118a to be in contact with the entire surface of the light emitting diodes LED. Further, the organic insulating layer OL may comprise a third part OL3 of the organic insulating layer OL which permeates between the third passivation layer 117 and the light emitting diode LED while being formed on the entire surface of the substrate 110 to serve as an adhesive between the third passivation layer 117 and the light emitting diode LED.

Next, referring to FIG. 5C, the organic insulating layer OL is patterned to remove a part of the organic insulating layer OL disposed at the inside of the opening 118a. A part of the organic insulating layer OL which covers a side surface of the first upper planarization layer 118, a side surface of the light emitting diode LED, and an upper portion of the light emitting diode LED may be removed from the opening 118a by a patterning process. For example, as illustrated in FIG. 3, a rectangular area of the organic insulating layer OL on a plane may be removed by an ashing process. Therefore, a part of the first part OL1 of the organic insulating layer OL which covers a side surface of the light emitting diode LED and a part of the second part OL2 which covers a top surface of the light emitting diode LED may remain. Therefore, the organic insulating layer OL fixes the light emitting diode LED during a subsequent process to suppress the light emitting diode LED from being separated.

At this time, a part of the third passivation layer 117 disposed below the organic insulating layer OL may be removed together. For example, the third passivation layer 117 may be removed from a part excluding the first part OL1 and the third part of the organic insulating layer OL from the opening 118a. Therefore, a part of the top surface of the first assembly line 121 and a part of the top surface of the second assembly line 122 may be exposed.

Next, referring to FIG. 5D, a conductive layer CL is formed on the entire surface of the substrate 110. Specifically, a conductive layer CL may be formed so as to cover the first upper planarization layer 118 and the light emitting diode LED. Specifically, the conductive layer CL may be formed to be in contact with the top surface of the first assembly line 121 and the top surface of the second assembly line 122 which are exposed by the third passivation layer 117 at the inside of the opening 118a.

Next, referring to FIG. 5E, a part of the conductive layer CL disposed on the organic insulating layer OL and the first upper planarization layer 118 is removed by an etching process. For example, only the conductive layer CL disposed on the top surface of the first assembly line 121 and the top surface of the second assembly line 122 which are exposed by the contact hole of the third passivation layer 117 at the inside of the opening 118a may remain. Accordingly, the contact electrode CE which is in contact with the side surface of the first semiconductor layer 131 may be formed.

Next, referring to FIG. 5E, a second upper planarization layer 119 is formed on the entire surface of the substrate 110. The second upper planarization layer 119 may be filled in an area from which the first upper planarization layer 118 is removed. For example, the second upper planarization layer is disposed in an area excluding the organic insulating layer OL at the inside of the opening 118a to cover the contact electrode CE and the light emitting diode LED. Therefore, the second upper planarization layer 119 may cover the light emitting diode LED together with the organic insulating layer OL, at the inside of the opening 118a.

Next, referring to FIG. 5F, the pixel electrode PE is formed on the second upper planarization layer 119. Specifically, a contact hole is formed in a part of the second upper planarization layer 119 on the light emitting diode LED so that the pixel electrode PE may be connected to the light emitting diode LED.

When the display device is manufactured by self-assembling the light emitting diode at the inside of the opening, the plurality of light emitting diodes is fixed onto the substrate by a bonding layer disposed below the plurality of light emitting diodes. For example, the organic layer is entirely coated on the substrate so that the organic layer permeates below the light emitting diode after self-assembling the plurality of light emitting diodes. Thereafter, the organic layer is removed from the remaining area excluding the organic layer disposed below the plurality of light emitting diodes to fix the plurality of light emitting diodes to the substrate using the organic layer disposed below the plurality of light emitting diodes as a bonding layer. In this case, the bonding layer is disposed only on the bottom surface of the light emitting diode so that a fixing force of the light emitting diode onto the substrate may been weakened. Therefore, when the contact electrode, the second upper planarization layer, and the pixel electrode are formed on the light emitting diode after self-assembling the light emitting diode at the inside of the opening, the light emitting diode is not fixed to move. Further, the light emitting diode is separated in the opening or moves, so that there may be a problem in that a contact defect may be caused during the process of forming the contact electrode and others on the light emitting diode. Further, in order to remove all the areas excluding the organic layer disposed below the plurality of light emitting diodes, among organic layers disposed in the entire surface of the substrate, a process of removing organic layers with a large thickness is performed so that an efficiency of the process is degraded.

In the display device 100 according to the exemplary embodiment of the present disclosure, after self-assembling the light emitting diode LED at the inside of the opening 118a on the substrate 110, the organic insulating layer OL which fixes the light emitting diode LED may be formed to be in contact with at least the top surface of the light emitting diode LED and the side surface of the light emitting diode LED. That is, the organic insulating layer OL may fix the light emitting diode LED to the inside of the opening 118a. Therefore, the fixing force of the light emitting diode LED and the substrate 110 may be improved and the separation of the light emitting diode LED may be suppressed. Further, an error generated due to the movement of the light emitting diode LED during a process of performing a subsequent process of forming a contact electrode CE on the self-assembled light emitting diode LED may be suppressed.

Further, in the display device 100 according to the exemplary embodiment of the present disclosure, the first upper planarization layer 118 and the organic insulating layer OL are disposed also at the outside of the opening 118a. Therefore, a process of removing the first upper planarization layer 118 and the organic insulating layer OL is not performed at the outside of the opening 118a so that the efficiency of the process of removing the organic layer may be improved.

Further, in the display device 100 according to the exemplary embodiment of the present disclosure, the first upper planarization layer 118 and the organic insulating layer OL extend from the opening 118a to cover the pixel circuit of the sub pixel SP. Therefore, the organic insulating layer OL insulates the pixel circuit from the other component without adding a separate passivation layer to suppress the risk of the short circuit.

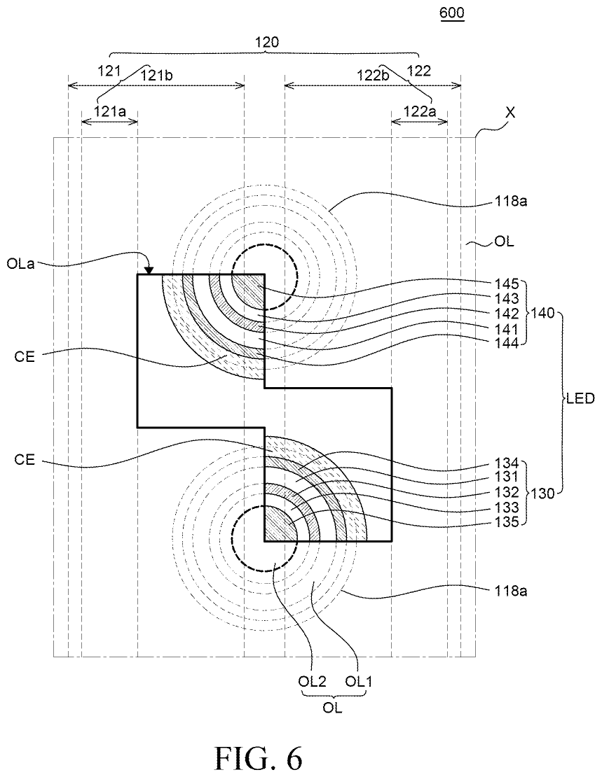

FIG. 6 is an enlarged plan view of a display device according to another exemplary embodiment of the present disclosure. The other configuration of the display device 600 of FIG. 6 is substantially the same as those of the display device 100 of FIGS. 1 to 5F except the contact electrode CE, the organic insulating layer OL, and the second upper planarization layer so that a redundant description will be omitted.

The organic insulating layer OL is disposed on the first upper planarization layer 118. The organic insulating layer OL includes a first part OL1, a second part OL2, and a third part.

The first part OL1 may be in contact with a part of a side surface of the light emitting diode LED in the opening 118a. The first part OL1 may overlap both the first assembly line 121 and the second assembly line 122 in the opening 118a. On a first light emitting diode 130, a size of an area of the first part OL1 which overlaps the first assembly line 121 may be different from a size of an area of the first part OL1 which overlaps the second assembly line 122. For example, the first part OL1 may overlap all the side surfaces of the first light emitting diode 130 disposed on the first assembly line 121. In the meantime, the first part OL1 may overlap a part of the side surfaces of the first light emitting diode 130 disposed on the second assembly line 122. As illustrated in FIG. 6, the first part OL1 may be disposed so as to overlap a half of the side surface of the first light emitting diode 130 disposed on the second assembly line 122, but is not limited thereto. Further, the first part OL1 may overlap a part of the side surfaces of a second light emitting diode 140 disposed on the first assembly line 121. As illustrated in FIG. 6, the first part OL1 may be disposed so as to overlap a half of the side surface of the second light emitting diode 140 disposed on the first assembly line 121, but is not limited thereto. In the meantime, the first part OL1 may overlap the entire side surface of the second light emitting diode 140 disposed on the second assembly line 122.

The second part OL2 is disposed on the plurality of light emitting diodes LED in the opening 118a. On the first light emitting diode 130, a size of an area of the second part OL2 which overlaps the first assembly line 121 may be different from a size of an area of the second part OL2 which overlaps the second assembly line 122. For example, the second part OL2 may overlap the entire top surface of the first light emitting diode 130 disposed on the first assembly line 121. In the meantime, the second part OL2 may overlap a part of the top surface of the first light emitting diode 130 disposed on the second assembly line 122. As illustrated in FIG. 6, the second part OL2 may be disposed so as to overlap a half of the top surface of the first light emitting diode 130 disposed on the second assembly line 122, but is not limited thereto. Further, the second part OL2 may overlap a part of the top surface of the second light emitting diode 140 disposed on the first assembly line 121. As illustrated in FIG. 6, the second part OL2 may be disposed so as to overlap a half of the top surface of the second light emitting diode 140 disposed on the first assembly line 121, but is not limited thereto. In the meantime, the second part OL2 may overlap the entire top surface of the second light emitting diode 140 disposed on the second assembly line 122.

Even though it is not illustrated in FIG. 6, the third part is disposed in a space between the third passivation layer 117 and the light emitting diode LED to be in contact with a bottom surface of the light emitting diode LED.

The contact electrode CE is disposed at the inside of the opening 118a. The contact electrode CE is disposed in an area excluding an area in which the first part OL1 of the organic insulating layer OL is disposed. Therefore, an area that the side surface of the light emitting diode LED and the contact electrode CE are in contact with each other may be smaller than an area that a side surface of the light emitting diode LED and the first part OL1 are in contact with each other.

Even though it is not illustrated in FIG. 6, a second upper planarization layer is disposed on the organic insulating layer OL and in an organic insulating layer opening OLa in which the organic insulating layer is not formed.

The second upper planarization layer may be filled in the opening 118a in an area excluding an area of the opening 118a in which the organic insulating layer OL is disposed. Therefore, the second upper planarization layer may be disposed on the contact electrode CE at the inside of the opening 118a.

The second upper planarization layer may be in contact with a part of side surfaces of the plurality of light emitting diodes LED and a part of top surfaces of the light emitting diodes LED in the opening 118a.

The second upper planarization layer includes a contact hole which exposes a part of the top surface of the light emitting diode LED. The pixel electrode PE is disposed in the contact hole of the second upper planarization layer 119 to be electrically connected to the second electrodes 135 and 145 of the plurality of light emitting diodes LED.

In the display device 600 according to another exemplary embodiment of the present disclosure, after self-assembling the light emitting diode LED at the inside of the opening 118a on the substrate 110, the organic insulating layer OL which fixes the light emitting diode LED may be formed to be in contact with at least a top surface of the light emitting diode LED and a side surface of the light emitting diode LED. Therefore, the fixing force of the light emitting diode LED and the substrate 110 may be improved and the separation of the light emitting diode LED may be suppressed.

Further, in the display device 600 according to another exemplary embodiment of the present disclosure, a process of removing the first upper planarization layer 118 and the organic insulating layer OL is not performed at the outside of the opening 118a so that the efficiency of the process of removing the organic layer may be improved.

Further, in the display device 600 according to another exemplary embodiment of the present disclosure, the first upper planarization layer 118 and the organic insulating layer OL insulate the pixel circuit from the other component without adding a separate passivation layer to suppress the risk of the short circuit.

Further, in the display device 600 according to another exemplary embodiment of the present disclosure, the organic insulating layer OL may cover a half or more of the area of the top surface of the light emitting diode LED and a half or more of the side surface of the light emitting diode LED. Therefore, the fixing force of the light emitting diode LED and the substrate 110 may be improved and the separation of the light emitting diode LED may be suppressed.

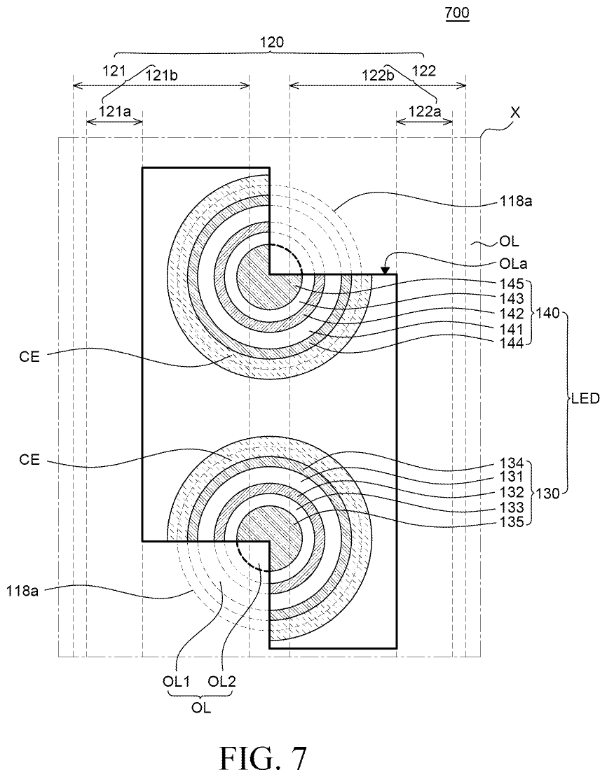

FIG. 7 is an enlarged plan view of a display device according to still another exemplary embodiment of the present disclosure. The other configuration of the display device 700 of FIG. 7 is substantially the same as those of the display device 100 of FIGS. 1 to 5F except the contact electrode CE, the organic insulating layer OL, and the second upper planarization layer so that a redundant description will be omitted.

The organic insulating layer OL is disposed on the first upper planarization layer 118. The organic insulating layer OL includes a first part OL1, a second part OL2, and a third part.

The first part OL1 may be in contact with a part of a side surface of the light emitting diode LED in the opening 118a. The first part OL1 which is in contact with the first light emitting diode 130 overlaps one of the first assembly line 121 and the second assembly line 122 and the first part OL1 which is in contact with the second light emitting diode 140 overlaps the other one of the first assembly line 121 and the second assembly line 122. For example, as illustrated in FIG. 7, the first part OL1 may be disposed only in an area of the side surface of the first light emitting diode 130 overlapping the first assembly line 121. In the meantime, the first part OL1 may be disposed only in the area of the side surface of the second light emitting diode 140 which overlaps the second assembly line 122. In the meantime, even though in FIG. 7, it is illustrated that the first part OL1 is disposed only in an area corresponding to a quarter of the side surface of the first light emitting diode 130 and an area corresponding to a quarter of the side surface of the second light emitting diode 140. However, the position of the first part OL1 is not limited thereto.

The second part OL2 is disposed on the plurality of light emitting diodes LED in the opening 118a. The second part OL2 which is in contact with the first light emitting diode 130 overlaps one of the first assembly line 121 and the second assembly line 122 and the second part OL2 which is in contact with the second light emitting diode 140 may overlap the other one of the first assembly line 121 and the second assembly line 122. For example, as illustrated in FIG. 7, the second part OL2 may be disposed only in an area of the side surface of the first light emitting diode 130 overlapping the first assembly line 121. In the meantime, the second part OL2 may be disposed only in the area of the side surface of the second light emitting diode 140 which overlaps the second assembly line 122. In the meantime, even though in FIG. 7, it is illustrated that the second part OL2 is disposed only in an area corresponding to a quarter of the side surface of the first light emitting diode 130 and an area corresponding to a quarter of the side surface of the second light emitting diode 140, the position of the second part OL2 is not limited thereto.

Even though it is not illustrated in FIG. 7, the third part is disposed in a space between the third passivation layer 117 and the light emitting diode LED to be in contact with a bottom surface of the light emitting diode LED.

The contact electrode CE is disposed at the inside of the opening 118a. The contact electrode CE is disposed in an area excluding an area in which the first part OL1 of the organic insulating layer OL is disposed. Therefore, the contact electrode CE may be disposed so as to overlap a half or more of the side surface of the light emitting diode LED. Therefore, an area that the side surface of the light emitting diode LED and the contact electrode CE are in contact with each other may be larger than an area in which a side surface of the light emitting diode LED and the first part OL1 are in contact with each other.

Even though it is not illustrated in FIG. 7, the second upper planarization layer is disposed on the organic insulating layer OL and in an organic insulating layer opening OLa in which the organic insulating layer is not formed.

The second upper planarization layer may be filled in the opening 118a in an area excluding an area of the opening 118a in which the organic insulating layer OL is disposed. Therefore, the second upper planarization layer may be disposed on the contact electrode CE at the inside of the opening 118a.

The second upper planarization layer may be in contact with a part of side surfaces of the plurality of light emitting diodes LED and a part of top surfaces of the light emitting diodes LED in the opening 118a.

The second upper planarization layer includes a contact hole which exposes a part of the top surface of the light emitting diode LED. The pixel electrode PE is disposed in the contact hole of the second upper planarization layer 119 to be electrically connected to the second electrodes 135 and 145 of the plurality of light emitting diodes LED.

In the display device 700 according to still another exemplary embodiment of the present disclosure, after self-assembling the light emitting diode LED at the inside of the opening 118a on the substrate 110, the organic insulating layer OL which fixing the light emitting diode LED may be formed to be in contact with at least a top surface and a side surface of the light emitting diode LED. Therefore, the fixing force of the light emitting diode LED and the substrate 110 may be improved and the separation of the light emitting diode LED may be suppressed.

Further, in the display device 700 according to still another exemplary embodiment of the present disclosure, a process of removing the first upper planarization layer 118 and the organic insulating layer OL is not performed at the outside of the opening 118a so that the efficiency of the process of removing the organic layer may be improved.

Further, in the display device 700 according to still another exemplary embodiment of the present disclosure, the first upper planarization layer 118 and the organic insulating layer OL insulate the pixel circuit from the other component without adding a separate passivation layer to suppress the risk of the short circuit.

Further, in the display device 700 according to still another exemplary embodiment of the present disclosure, an area that the side surface of the light emitting diode LED and the contact electrode CE are in contact with each other may be larger than an area that a side surface of the light emitting diode LED and the first part OL1 are in contact with each other. Therefore, a contact area of the light emitting diode LED and the contact electrode CE is increased to improve a contact resistance.

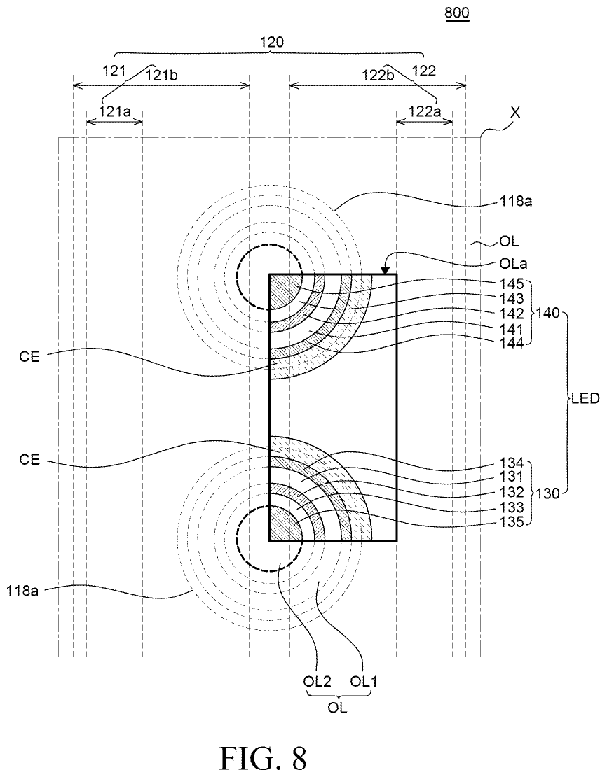

FIG. 8 is an enlarged plan view of a display device according to still another exemplary embodiment of the present disclosure. The other configuration of the display device 800 of FIG. 8 is substantially the same as those of the display device 100 of FIGS. 1 to 5F except the contact electrode CE, the organic insulating layer OL, and the second upper planarization layer so that a redundant description will be omitted.

The organic insulating layer OL is disposed on the first upper planarization layer 118. The organic insulating layer OL includes a first part OL1, a second part OL2, and a third part.

The first part OL1 may be in contact with a part of a side surface of the light emitting diode LED in the opening 118a. A size of an area of the first part OL1 which overlaps the first assembly line 121 may be different from a size of an area of the first part OL1 which overlaps the second assembly line 122. The first part OL1 completely overlaps one of the first assembly line 121 and the second assembly line 122 and partially overlaps the other one. For example, as illustrated in FIG. 8, the first part OL1 completely overlaps the first assembly line 121 between the first assembly line 121 and the second assembly line 122 and may partially overlap the second assembly line 122. Therefore, the first part OL1 may overlap a half or more of a side surface of the light emitting diode LED.

The second part OL2 is disposed on the plurality of light emitting diodes LED in the opening 118a. A size of an area of the second part OL2 which overlaps the first assembly line 121 may be different from a size of an area of the second part OL2 which overlaps the second assembly line 122. For example, as illustrated in FIG. 8, the second part OL2 completely overlaps the first assembly line 121 between the first assembly line 121 and the second assembly line 122 and may partially overlap the second assembly line 122. Therefore, the second part OL2 may overlap a half or more of a top surface of the light emitting diode LED.

Even though it is not illustrated in FIG. 8, the third part is disposed in a space between the third passivation layer 117 and the light emitting diode LED to be in contact with a bottom surface of the light emitting diode LED.

The contact electrode CE is disposed at the inside of the opening 118a.

The contact electrode CE is disposed in an area excluding an area in which the first part OL1 of the organic insulating layer OL is disposed. Therefore, an area that the side surface of the light emitting diode LED and the contact electrode CE are in contact with each other may be smaller than an area that a side surface of the light emitting diode LED and the first part OL1 are in contact with each other.

Even though it is not illustrated in FIG. 8, the second upper planarization layer is disposed on the organic insulating layer OL and in an organic insulating layer opening OLa in which the organic insulating layer is not formed.

The second upper planarization layer may be filled in the opening 118a in the organic insulating layer opening OLa of the opening 118a. Therefore, the second upper planarization layer may be disposed on the contact electrode CE at the inside of the opening 118a.

The second upper planarization layer may be in contact with a part of side surfaces of the plurality of light emitting diodes LED and a part of top surfaces of the light emitting diodes LED in the opening 118a.

The second upper planarization layer includes a contact hole which exposes a part of the top surface of the light emitting diode LED. The pixel electrode PE is disposed in the contact hole of the second upper planarization layer 119 to be electrically connected to the second electrodes 135 and 145 of the plurality of light emitting diodes LED.

In the display device 800 according to still another exemplary embodiment of the present disclosure, after self-assembling the light emitting diode LED at the inside of the opening 118a on the substrate 110, the organic insulating layer OL which fixing the light emitting diode LED may be formed to be in contact with at least a top surface and a side surface of the light emitting diode LED. Therefore, the fixing force of the light emitting diode LED and the substrate 110 may be improved and the separation of the light emitting diode LED may be suppressed.

Further, in the display device 800 according to still another exemplary embodiment of the present disclosure, a process of removing the first upper planarization layer 118 and the organic insulating layer OL is not performed at the outside of the opening 118a so that the efficiency of the process of removing the organic layer may be improved.

Further, in the display device 800 according to still another exemplary embodiment of the present disclosure, the first upper planarization layer 118 and the organic insulating layer OL insulate the pixel circuit from the other component without adding a separate passivation layer to suppress the risk of the short circuit.

Further, in the display device 800 according to still another exemplary embodiment of the present disclosure, the organic insulating layer OL may cover a half or more of the area of the top surface of the light emitting diode LED and a half or more of the side surface of the light emitting diode LED. Therefore, the fixing force of the light emitting diode LED and the substrate 110 may be improved and the separation of the light emitting diode LED may be suppressed.

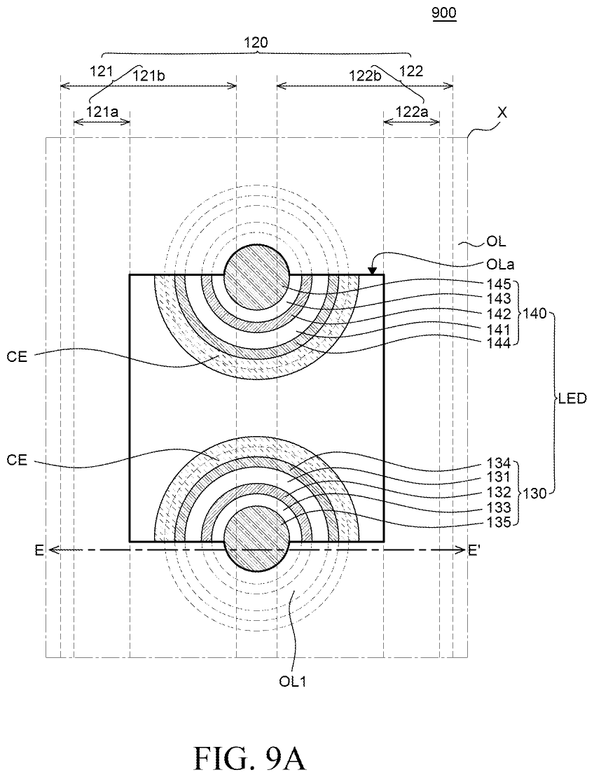

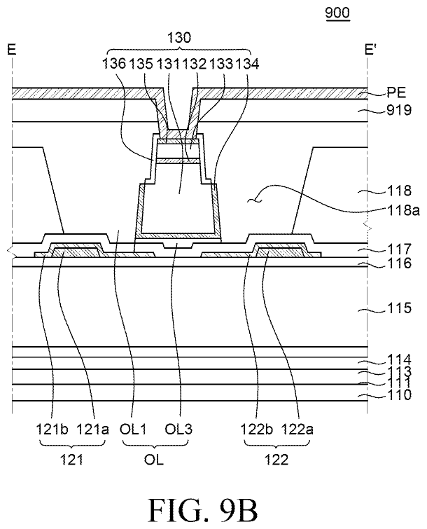

FIG. 9A is an enlarged plan view of a display device according to still another exemplary embodiment of the present disclosure. FIG. 9B is a cross-sectional view taken along the line E-E′ of FIG. 9A. The other configuration of the display device 900 of FIGS. 9A and 9B is substantially the same as those of the display device 100 of FIGS. 1 to 5F except the organic insulating layer OL, the second part OL2, the second upper planarization layer 919, and the pixel electrode PE so that a redundant description will be omitted.

The organic insulating layer OL is disposed on the first upper planarization layer 118. The organic insulating layer OL may cover a part of a side surface of the plurality of light emitting diodes LED. The organic insulating layer OL includes a first part OL1 and a third part OL3.

The first part OL1 is a part which is disposed to be in contact with a side surface of the plurality of light emitting diodes LED to cover a part of a side surface of the light emitting diode LED.

The third part OL3 is disposed in a space between the third passivation layer 117 and the light emitting diode LED to be in contact with a bottom surface of the light emitting diode LED.

In the meantime, the organic insulating layer OL may not be disposed on top surfaces of the plurality of light emitting diodes LED. Therefore, as illustrated in FIG. 9A, the organic insulating layer OL may expose the second electrodes 135 and 145 disposed on the top surfaces of the plurality of light emitting diodes LED.

The contact electrode CE is disposed in an area excluding an area in which the first part OL1 of the organic insulating layer OL is disposed to electrically connect the first electrodes 134 and 144 of the light emitting diode LED and the first assembly line 121 and the second assembly line 122.

Referring to FIG. 9B, the second upper planarization layer 919 is disposed on the organic insulating layer OL and an organic insulating layer opening OLa in which the organic insulating layer is not formed.

The second upper planarization layer 919 may be filled in the opening 118a in an area excluding an area of the opening 118a in which the organic insulating layer OL is disposed. Therefore, the second upper planarization layer 919 may be disposed on the contact electrode CE at the inside of the opening 118a.

The second upper planarization layer 919 includes a contact hole which exposes a top surface of the light emitting diode LED. The pixel electrode PE is disposed in the contact hole of the second upper planarization layer 919 to be electrically connected to the second electrodes 135 and 145 of the plurality of light emitting diodes LED.

The pixel electrode PE which electrically connects the plurality of light emitting diodes LED and the connection electrode 150 is disposed on the second upper planarization layer 919.

In the display device 900 according to still another exemplary embodiment of the present disclosure, after self-assembling the light emitting diode LED at the inside of the opening 118a on the substrate 110, the organic insulating layer OL which fixes the light emitting diode LED may be formed to be in contact with the side surface of the light emitting diode LED. Therefore, the fixing force of the light emitting diode LED and the substrate 110 may be improved and the separation of the light emitting diode LED may be suppressed.

Further, in the display device 900 according to still another exemplary embodiment of the present disclosure, a process of removing the first upper planarization layer 118 and the organic insulating layer OL is not performed at the outside of the opening 118a so that the efficiency of the process of removing the organic layer may be improved.

Further, in the display device 900 according to still another exemplary embodiment of the present disclosure, the first upper planarization layer 118 and the organic insulating layer OL insulate the pixel circuit from the other component without adding a separate passivation layer to suppress the risk of the short circuit.

Further, in the display device 900 according to another exemplary embodiment of the present disclosure, the organic insulating layer OL may be disposed in an area excluding the top surface of the light emitting diode LED. Therefore, front surfaces of the second electrodes 135 and 145 disposed on the top surface of the light emitting diode LED may be in contact with the pixel electrode PE. Therefore, a contact resistance of the light emitting diode LED and the pixel electrode PE may be improved.

The exemplary embodiments disclosed in the present disclosure are provided not to limit the technical spirit of the present disclosure, but explain. The more the area in which the organic insulating layer OL remains, the stronger the fixing force of the light emitting diode LED and the more the area which opens the organic insulating layer OL, the more stable the contact with the pixel electrode PE. In order to ensure proper fixing force and contact area depending on a size and a design of the light emitting diode LED, various ways may be used.

The exemplary embodiments of the present disclosure can also be described as follows:

According to an aspect of the present disclosure, there is provided a display device. The display device comprises a substrate including a plurality of sub pixels, a first assembly line and a second assembly line which are disposed in the plurality of sub pixels on the substrate and are spaced apart from each other, a first upper planarization layer which is disposed on the first assembly line and the second assembly line and has an opening overlapping the first assembly line and the second assembly line, a light emitting diode which is disposed on the opening and includes a first electrode, a first semiconductor layer, an emission layer, a second semiconductor layer, and a second electrode, a contact electrode which electrically connects the first assembly line and the second assembly line and the first electrode, and an organic insulating layer which is disposed above the first upper planarization layer and in a part of the opening and covers a part of a side surface of the light emitting diode.

The organic insulating layer may include a first part which may be in contact with the side surface of the light emitting diode in a part excluding a part of the side surface of the light emitting diode which may be in contact with the contact electrode.

The display device may further comprise a second upper planarization layer disposed on the light emitting diode and the organic insulating layer, wherein the second upper planarization layer may be disposed to be filled in a part of the opening.

The second upper planarization layer may be disposed to be filled in an organic insulating layer opening of the opening.

The light emitting diode may include a first light emitting diode and a second light emitting diode disposed in each of the plurality of sub pixels, the first part which is in contact with the first light emitting diode may overlap one of the first assembly line and the second assembly line and the first part which is in contact with the second light emitting diode may overlap the other one of the first assembly line and the second assembly line.

The light emitting diode may include a first light emitting diode and a second light emitting diode disposed in each of the plurality of sub pixels and the first part which is in contact with the first light emitting diode and the first part which is in contact with the second light emitting diode may overlap both the first assembly line and the second assembly line.

A planar shape of the second upper planarization layer disposed in the organic insulating layer opening may have a rectangular shape.

A size of the area of the first part which overlaps the first assembly line may be equal to a size of the area of the first part which overlaps the second assembly line.

A size of the area of the first part which overlaps the first assembly line may be different from a size of the area of the first part which overlaps the second assembly line.

The first part may completely overlap one of the first assembly line and the second assembly line and partially overlaps the other one.

An area in which the side surface of the light emitting diode and the contact electrode are in contact with each other may be larger than an area in which the side surface of the light emitting diode and the first part are in contact with each other.

An area in which the side surface of the light emitting diode and the contact electrode are in contact with each other may be smaller than an area in which the side surface of the light emitting diode and the first part are in contact with each other.

The organic insulating layer may further include a second part which covers a part of a top surface of the light emitting diode.

The display device may further comprise a transistor disposed on the substrate, and a pixel electrode which electrically connects the transistor and the second electrode, wherein the pixel electrode is in contact with the second electrode in an area excluding an area of the top surface of the light emitting diode in which the second part is disposed.

The side surface of the second part may be disposed along a part of a circumference of the second electrode.

The organic insulating layer may further include a third part disposed below the light emitting diode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on all the technical concepts discussed and in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a plurality of sub pixels;
a first assembly line and a second assembly line which are disposed in the plurality of sub pixels on the substrate and are spaced apart from each other;
a first upper planarization layer which is disposed on the first assembly line and the second assembly line;
an opening in the first upper planarization layer, the opening overlapping the first assembly line and the second assembly line;
a light emitting diode which is disposed in the opening and includes a first electrode and a second electrode on the first electrode, the light emitting diode having a side surface and a top surface;
a contact electrode which electrically connects with the first assembly line, the second assembly line, and the first electrode; and
an organic insulating layer which is disposed in a part of the opening and covers a part of the side surface of the light emitting diode.

2. The display device according to claim 1, wherein a part of the side surface of the light emitting diode is in contact with a first part of the organic insulating layer, and another part of the side surface of the light emitting diode is in contact with the contact electrode.

3. The display device according to claim 2, further comprising:
a second upper planarization layer disposed on the light emitting diode and the organic insulating layer,
wherein the second upper planarization layer is in a part of the opening.

4. The display device according to claim 3, wherein the opening includes an organic insulating layer opening, and
wherein the second upper planarization layer is in the organic insulating layer opening of the opening.

5. The display device according to claim 2, wherein the light emitting diode includes a first light emitting diode and a second light emitting diode disposed in each of the plurality of sub pixels, the first part which is in contact with the first light emitting diode overlaps one of the first assembly line and the second assembly line and the first part which is in contact with the second light emitting diode overlaps the other one of the first assembly line and the second assembly line.

6. The display device according to claim 2, wherein the light emitting diode includes a first light emitting diode and a second light emitting diode disposed in each of the plurality of sub pixels and the first part which is in contact with the first light emitting diode and the first part which is in contact with the second light emitting diode overlaps both the first assembly line and the second assembly line.

7. The display device according to claim 4, wherein a planar shape of the second upper planarization layer disposed in the organic insulating layer opening has a rectangular shape.

8. The display device according to claim 6, wherein a size of the area of the first part which overlaps the first assembly line is equal to a size of the area of the first part which overlaps the second assembly line.

9. The display device according to claim 6, wherein a size of the area of the first part which overlaps the first assembly line is different from a size of the area of the first part which overlaps the second assembly line.

10. The display device according to claim 6, wherein the first part completely overlaps one of the first assembly line and the second assembly line and partially overlaps the other one.

11. The display device according to claim 2, wherein an area in which the side surface of the light emitting diode and the contact electrode are in contact with each other is larger than or equal to an area in which the side surface of the light emitting diode and the first part are in contact with each other.

12. The display device according to claim 2, wherein an area in which the side surface of the light emitting diode and the contact electrode are in contact with each other is smaller than an area in which the side surface of the light emitting diode and the first part are in contact with each other.

13. The display device according to claim 1, wherein the organic insulating layer further includes a second part which covers a part of the top surface of the light emitting diode.

14. The display device according to claim 13, further comprising:
a transistor disposed on the substrate; and
a pixel electrode which electrically connects the transistor and the second electrode,
wherein the pixel electrode is in contact with the second electrode in an area excluding an area of the top surface of the light emitting diode in which the second part is disposed.

15. The display device according to claim 13, wherein a side surface of the second part is disposed along a part of a circumference of the second electrode.

16. The display device according to claim 1, wherein the organic insulating layer further includes a third part disposed below the light emitting diode.

17. The display device according to claim 1, wherein each of the first assembly line and the second assembly line comprises a conductive layer and a clad layer covering a top surface and a side surface of the conductive layer, the conductive layer does not overlap with the light emitting diode, and the clad layer overlaps with the light emitting diode.

18. The display device according to claim 1, wherein the second upper planarization layer is disposed on the contact electrode at the inside of the opening.

19. The display device according to claim 2, wherein the first part extends to the outside of the opening and is disposed on the first upper planarization layer.

20. A display device, comprising:
a substrate;
a plurality of assembly lines on the substrate and are spaced apart from each other;
a first upper planarization layer on the plurality of assembly lines;
an opening in the first upper planarization layer;
an organic insulating layer;
a light emitting diode disposed in the opening, the light emitting diode having a side surface; and
a contact electrode disposed in the opening,
wherein the contact electrode is disposed to contact with the plurality of assembly lines and the light emitting diode, and
wherein the organic insulating layer overlaps with the plurality of assembly lines in the opening and is contact with the side surface of the light emitting diode.
